(19) United States
(12) Patent Application Publication
(10) Pub. No.: US 2007/0014159 A1
(43) Pub. Date: Jan. 18, 2007

(54) Under voltage protection device

(75) Inventors: Chien-Hua Chen, Taoyuan Hsien (TW); Wen-Shi Huang, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/402,820

(22) Filed: Apr. 13, 2006

(30) Foreign Application Priority Data
Jun. 30, 2005 (TW) 094122132

(51) Int. Cl. G11C 11/34

(52) U.S. Cl. 365/185.22

(57) ABSTRACT

An under voltage protection device is for cooperating with a fan. The under voltage protection device includes a voltage detective unit and a starting unit. The voltage detective unit is for receiving an input voltage and a reference voltage. The starting unit is electrically connected to the voltage detective unit and the fan, and starts the fan according to the input voltage. The voltage detective unit shuts the starting unit down if the input voltage is lower than the reference voltage.

### BACKGROUND OF THE INVENTION

1. Field of Invention

The present invention relates to an under voltage protection device, and more particularly to an under voltage protection device capable of determining a normal operation or shutting down to the fan.

2. Related Art

An electronic system usually has at least one fan for thermal dissipation to maintain a normal operation of the electronic system. The power of the fan is provided by the electronic system directly or by an exterior voltage source indirectly. If the voltage generated by the voltage source is not stable, for example the current rises to form an over current phenomenon caused by the too-low voltage, the interior elements of the fan may be damaged. Typically, an analog control chip is used to perform an under voltage detection. However, the analog control chip has a high price, and the cost of the electronic system is thus too high.

Therefore, it is imperative to provide an under voltage protection device to solve the above-mentioned problem.

### SUMMARY OF THE INVENTION

In view of the foregoing, the present invention provides an under voltage protection device for shutting a fan down if an input voltage is too-low so as to protect the interior elements of the fan when an under voltage occurs. Furthermore, the under voltage protection device can replace the conventional analog control chip to reduce the cost.

To achieve the above, an under voltage protection device according to the present invention is for cooperating with a fan. The under voltage protection device includes a voltage detective unit and a starting unit. The voltage detective unit is for receiving an input voltage and a reference voltage. The starting unit is electrically connected to the voltage detective unit and the fan, and starts the fan according to the input voltage. The voltage detective unit shuts the starting unit down if the input voltage is lower than the reference voltage.

To achieve the above, another under voltage protection device according to the present invention is for cooperating with a fan. The under voltage protection device includes a starting unit and a voltage detective unit. The starting unit is electrically connected to the fan and includes a first switch element and a second switch element. The first switch element has one end for receiving an input voltage, and the second switch element has one end electrically connected to the first switch element. The voltage detective unit is electrically connected to the starting unit and includes a comparator. The comparator has a first input terminal for receiving the input voltage, a second input terminal for receiving a reference voltage and an output terminal electrically connected to the second switch element. The first switch element and the second switch element turn off if the input voltage is lower than the reference voltage.

As mentioned above, an under voltage protection device according to the present invention utilizes the voltage detective unit to detect whether the input voltage is too low, and shuts the starting unit down if the input voltage is too low. Thus, it can prevent the interior elements of the fan from damage through an over current caused by the too-low input voltage. Comparing with the prior art, the under voltage protection device of the present invention only needs a simple circuit composed of a comparator and transistors to achieve the effect of under voltage protection and replace the analog control chip to reduce the cost.

### BRIEF DESCRIPTION OF THE DRAWINGS

The present invention will become more fully understood from the detailed description given herein below illustration only, and thus are not limitative of the present invention, and wherein:

FIG. 1 is a block diagram showing an under voltage protection device according to a preferred embodiment of the present invention; and

FIG. 2 is a circuit diagram showing an under voltage protection device according to the preferred embodiment of the present invention.

### DETAILED DESCRIPTION OF THE INVENTION

The present invention will be apparent from the following detailed description, which proceeds with reference to the accompanying drawings, wherein the same numerals refer to the same elements.

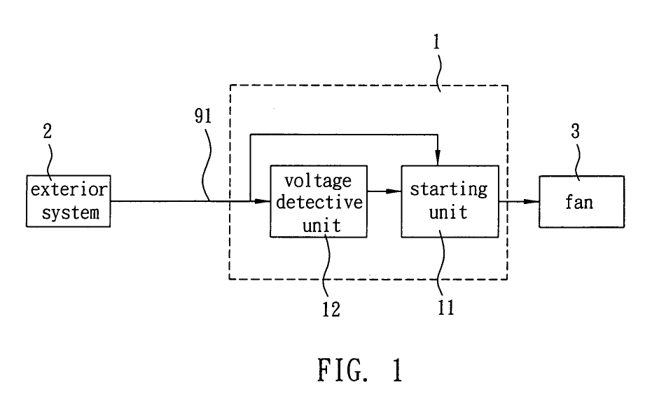

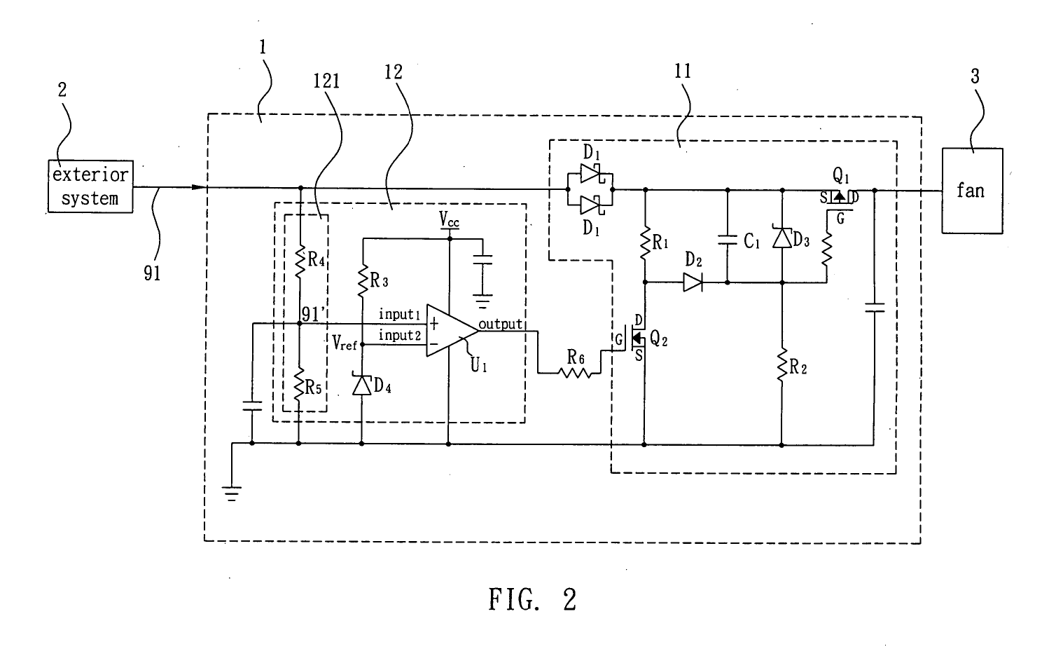

FIGS. 1 and 2 are respectively a block diagram and a circuit diagram showing an under voltage protection device according to a preferred embodiment of the present invention. As shown in FIG. 1, an under voltage protection device 1 is for cooperating with a fan 3. The under voltage protection device 1 includes a starting unit 11 and a voltage detective unit 12. The voltage detective unit 12 is for receiving an input voltage 91 and a reference voltage V_{ref}. Herein, the input voltage 91 provided by an exterior system 2 provides electric energy to drive the subsequent circuits.

As shown in FIG. 2, the starting unit 11 has two first diodes D₁, a plurality of resistors R₁ and R₂, a first switch element Q₁, a second switch element Q₂, a second diode D₂, a Zener diode D₃ and a capacitor C₁. The first switch element Q₁ and the second switch element Q₂ may be transistors or other electrical elements having the switching function.

The first diodes D₁ are connected in parallel, and one end of each of the first diodes D₁ is electrically connected to the exterior system 2 to receive the input voltage 91. In this embodiment, the first diodes D₁ may be Schottky diodes for avoiding a reverse current.

One end of the resistor R₁ is electrically connected to the other end of each of the first diodes D₁.

In this embodiment, the first switch element Q₁ is a PMOS transistor and the second switch element Q₂ is a NMOS transistor. The first switch element Q₁ has a source S electrically connected to the other end of each of the first diodes D₁, and a drain D electrically connected to the fan 3. The second switch element Q₂ has a drain D electrically connected to the other end of the resistor R₁.

In addition, the second diode D₂ has one end electrically connected to the drain D of the second switch element Q₂ and the other end electrically connected to a gate G of the first switch element Q₁. The Zener diode D₃ has one end electrically connected to the source S of the first switch element Q₁ and the other end electrically connected to the other end of the second diode D₂. The capacitor C₁ has one end electrically connected to the source S of the first switch element Q₁, and the other end electrically connected to one end of the resistor R₂. The other end of the resistor R₂ is grounded.

When the starting unit 11 operates, the one end of the first diodes D₁ receive the input voltage 91 from the exterior system 2 such that the capacitor C₁ starts to be charged. When the voltage value of the capacitor C₁ reaches the starting voltage of the first switch element Q₁, the first switch element Q₁ is turned on to start the fan 3. In addition, this embodiment has the function of soft-start by slowly increasing the current flowing through the fan 3 according to a charging circuit composed of the capacitor C₁ and the resistor R₂.

The voltage detective unit 12 receives the input voltage 91 and shuts the starting unit 11 down if the input voltage 91 is lower than the reference voltage V_{ref} so as to stop the fan 3 and achieve the effect of under voltage protection. The voltage detective unit 12 includes a resistor R₃, a Zener diode D₄, a comparator U₁ and a voltage-dividing unit 121.

In this embodiment, the resistor R₃ has one end electrically connected to an exterior voltage V_{cc}, and the other end electrically connected to one end of the Zener diode D₄. Herein, the reference voltage V_{ref} is generated according to the constant voltage property of the Zener diode D₄. The voltage value of the reference voltage V_{ref} may be determined according to the practical requirement, and is not particularly restricted.

The voltage-dividing unit 121 has two resistors R₄ and R₅. The resistor R₄ has one end for receiving the input voltage 91, and the other end electrically connected to one end of the resistor R₅. The other end of the resistor R₅ is grounded. Thus, a voltage-dividing circuit for generating the voltage-divided input voltage 91′ is formed. Because the input voltage 91 may be a larger voltage, the voltage-divided input voltage 91′ may have a lower voltage value to facilitate the subsequent operation after the input voltage 91 passes through the voltage-dividing unit 121. The value of the voltage-divided input voltage 91′ may be adjusted by adjusting the ratio of the resistance of the resistor R₄ to the resistance of the resistor R₅ according to the practical requirement.

The comparator U₁ has a first input terminal input, a second input terminal input2 and an output terminal “output”. The first input terminal input₁ is a non-inverting input terminal electrically connected to the other end of the resistor R₄, and receives the voltage-divided input voltage 91′. The second input terminal input₂ is an inverting input terminal electrically connected to the one end of the Zener diode D₄ and receives the reference voltage V_{ref}. The output terminal “output” is electrically connected to a gate G of the second switch element Q₂ through a resistor R₆, and controls the second switch element Q₂ to turn on or off.

The under voltage protection device 1 operates as follows. After the voltage detective unit 12 receives the voltage-divided input voltage 91′, the comparator U₁ compares the voltage-divided input voltage 91′ with the reference voltage V_{ref}. When the voltage-divided input voltage 91′ is higher than the reference voltage V_{ref}, the output terminal “output” outputs a positive voltage value to turn on the second switch element Q₂, and then the first switch element Q₁ is triggered to turn on and the fan 3 starts to operate.

On the contrary, when the voltage-divided input voltage 91′ is lower than the reference voltage V_{ref} the output terminal “output” outputs a negative voltage value. In this embodiment, the second switch element Q₂ is a NMOS transistor. So, the negative voltage value is regarded as a switch signal for turning off the second switch element Q₂. At this time, the second switch element Q₂ turns off and cannot trigger the first switch element Q₁. Thus, the first switch element Q₁ turns off and the fan 3 cannot operate such that the effect of under voltage protection is achieved.

In addition, the first input terminal input₁ of the comparator U₁ in another embodiment may also be electrically connected to the exterior system 2 (not shown) directly to receive the input voltage 91 and perform the subsequent comparison operation, which is similar to that as described hereinabove and the description thereof will thus be omitted.

In summary, an under voltage protection device according to the present invention utilizes the voltage detective unit to detect whether the input voltage is too low, and shuts the starting unit down if the input voltage is too low. Thus, it can prevent the interior elements of the fan from damage through an over current caused by the too-low input voltage. Comparing with the prior art, the under voltage protection device of the present invention only needs a simple circuit composed of a comparator and transistors to achieve the effect of under voltage protection and replace the analog control chip to reduce the cost.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. An under voltage protection device for cooperating with a fan, comprising:
a voltage detective unit for receiving an input voltage and a reference voltage; and
a starting unit electrically connected to the voltage detective unit and the fan, and starting the fan according to the input voltage;
wherein the voltage detective unit shuts the starting unit down if the input voltage is lower than the reference voltage.

2. The device according to claim 1, wherein the, voltage detective unit has a first input terminal for receiving the input voltage, a second input terminal for receiving the reference voltage, and an output terminal for outputting a switch signal to the starting unit if the input voltage is lower than the reference voltage.

3. The device according to claim 2, wherein the voltage detective unit comprises a comparator.

4. The device according to claim 3, wherein the output terminal is electrically connected to the starting unit through a resistor.

5. The device according to claim 1, wherein the starting unit comprising:
a first switch element having one end for receiving the input voltage; and
a second switch element having one end electrically connected to the first switch element;
wherein the first switch element and the second switch element turn off if the input voltage is lower than the reference voltage.

6. The device according to claim 5, wherein the starting unit further comprises a capacitor having one end electrically connected to the first switch element.

7. The device according to claim 5, wherein the starting unit further comprises at least one first diode having one end for receiving the input voltage and the other end electrically connected to the first switch element.

8. The device according to claim 7, wherein the first switch element and the second switch element are respectively PMOS and NMOS transistors, wherein a source of the first switch element is electrically connected to the other end of the first diode, a drain of the second switch element is electrically connected to the other end of the first diode, and a drain of the first switch element is electrically connected to the fan.

9. The device according to claim 5, wherein the voltage detective unit comprises:
a voltage-dividing unit receiving the input voltage and generating a voltage-divided input voltage; and
a comparator having a first input terminal for receiving the voltage-divided input voltage, a second input terminal for receiving the reference voltage, and an output terminal electrically connected to the second switch element.

10. The device according to claim 9, wherein the voltage-dividing unit comprises a first resistor having one end for receiving the input voltage and the other end electrically connected to the first input terminal, and a second resistor having one end electrically connected to the other end of the first resistor and the other end grounded.

11. The device according to claim 5, wherein the voltage detective unit comprises:
a resistor having one end electrically connected to an exterior voltage;
a Zener diode having one end electrically connected to the other end of the resistor; and
a comparator having a first input terminal for receiving the input voltage, a second input terminal electrically connected to the one end of the Zener diode, and an output terminal electrically connected to the second switch element.

12. The device according to claim 1, wherein the starting unit comprises:
at least one first diode having one end for receiving the input voltage;
a resistor having one end electrically connected to the other end of the first diode;
a first transistor having a source electrically connected to the other end of the first diode;
a second transistor having a drain electrically connected to the other end of the resistor;
a second diode having one end electrically connected to the drain of the second transistor and the other end electrically connected to a gate of the first transistor;
a Zener diode having one end electrically connected to the source of the first transistor and the other end electrically connected to the other end of the second diode; and
a capacitor having one end electrically connected to the source of the first transistor;
wherein the first transistor and the second transistor turn off if the input voltage is lower than the reference voltage.

13. The device according to claim 12, wherein the voltage detective unit comprises a comparator having a first input terminal for receiving the input voltage, a second input terminal for receiving the reference voltage, and an output terminal electrically connected to a gate of the second transistor.

14. An under voltage protection device for cooperating with a fan, comprising:
a starting unit electrically connected to the fan and comprising:
a first switch element having one end for receiving an input voltage; and
a second switch element having one end electrically connected to the first switch element; and
a voltage detective unit electrically connected to the starting unit and comprising:
a comparator having a first input terminal for receiving the input voltage, a second input terminal for receiving a reference voltage, and an output terminal electrically connected to the second switch element;
wherein the first switch element and the second switch element turn off if the input voltage is lower than the reference voltage.

15. The device according to claim 14, wherein the starting unit further comprises a capacitor having one end electrically connected to the first switch element.

16. The device according to claim 14, wherein the starting unit further comprises at least one first diode having one end for receiving the input voltage and the other end electrically connected to the first switch element.

17. The device according to claim 16, wherein the first switch element and the second switch element are respectively PMOS and NMOS transistors, wherein a source of the first switch element is electrically connected to the other end of the first diode, a drain of the second switch element is electrically connected to the other end of the first diode, and a drain of the first switch element is electrically connected to the fan.

18. The device according to claim 17, wherein the starting unit further comprises:
a resistor having one end electrically connected to the other end of the first diode;
a second diode having one end electrically connected to the drain of the second switch element and the other end electrically connected to a gate of the first switch element;
a Zener diode having one end electrically connected to the source of the first switch element and the other end electrically connected to the other end of the second diode; and
a capacitor having one end electrically connected to the source of the first switch element.

19. The device according to claim 14, wherein the voltage detective unit further comprises a voltage-dividing unit receiving the input voltage and generating a voltage-divided input voltage, and the first input terminal of the comparator receives the voltage-divided input voltage.

20. The device according to claim 19, wherein the voltage-dividing unit comprises a first resistor and a second resistor, the first resistor has one end for receiving the input voltage and the other end electrically connected to the first input terminal, and the second resistor has one end electrically connected to the other end of the first resistor and the other end grounded.
